(19) United States
(12) Patent Application Publication
(10) Pub. No.: US 2025/0280676 A1
(43) Pub. Date: Sep. 4, 2025

(54) TRANSPARENT DISPLAY APPARATUS

(71) Applicant: LG Display Co., Ltd., Seoul (KR)

(72) Inventor: Youngwan KIM, Paju-si (KR)

(21) Appl. No.: 18/951,296

(22) Filed: Nov. 18, 2024

(30) Foreign Application Priority Data
Feb. 29, 2024 (KR) 10-2024-0030283

(51) Int. Cl. H10K 59/131; H10K 59/122; H10K 59/88

(52) U.S. Cl. CPC H10K 59/131; H10K 59/122; H10K 59/88

(57) ABSTRACT

Disclosed is a transparent display apparatus including a substrate having a display area and a non-display area. The display area is provided with a transmission area and a non-transmission area including an emission area in which a light emitting element is disposed. The non-display area is provided in a periphery of the display area. The transparent display apparatus includes at least one power line disposed in the non-transmission area of the display area on the substrate and configured to extend in a first direction. The transparent display apparatus includes a power shorting bar disposed in the non-display area on the substrate, electrically connected to the at least one power line, and extending in a second direction transverse to the first direction. The transparent display apparatus includes at least one undercut line disposed in the display area and the non-display area on the substrate and extending in the first direction.

### CROSS-REFERENCE TO RELATED APPLICATION

This application claims priority to Korean Patent Application No. 10-2024-0030283 filed Feb. 29, 2024, the entire contents of which is hereby expressly incorporated by reference into the present application.

### BACKGROUND

### Technical Field

The present disclosure relates to a transparent display apparatus.

### Description of the Related Art

With the development of information society, the demand for a display apparatus for displaying an image is increasing in various forms. Accordingly, display apparatuses such as a liquid crystal display LCD apparatus, an organic light emitting display OLED apparatus, a micro light emitting diode LED display apparatus, a quantum dot display QD apparatus, and the like are used.

Recently, research on a transparent display apparatus has been actively conducted, which not only displays an image to a user, but also transmits light therethrough so that a user can see an object or image located behind the display apparatus. The transparent display apparatus includes a display area in which an image is displayed and a non-display area, wherein the display area may include a transmission area capable of transmitting external light and a non-transmission area. The transparent display apparatus may have a high light transmittance in the display area through the transmission area. The transparent display apparatus may include a plurality of touch sensors and a plurality of touch sensor lines to implement a touch function.

### BRIEF SUMMARY

In a transparent display apparatus, images and background can be viewed together and therefore, the transparent display apparatus is highly likely to be used in various fields. However, since there are various fields and uses to which transparent display apparatus is applied, the transparent display apparatus needs to be manufactured in various types and various sizes. However, when the transparent display apparatus is manufactured with various types and various sizes, a manufacturing cost and production energy increase due to the increase in the number of processes. Various embodiments of the present disclosure address the technical problems in the related art, including the problem identified above.

An aspect of the present disclosure is directed to providing a transparent display apparatus capable of lowering the occurrence of defects caused by a moisture permeation.

Another aspect of the present disclosure is directed to providing a transparent display apparatus capable of preventing the deterioration of process reliability by the formation of moisture permeation preventing structure.

Another aspect of the present disclosure is directed to providing a transparent display apparatus capable of being manufactured in various types (or various sizes).

The technical benefits of the present disclosure are not limited to the aforesaid, but other benefits not described herein will be clearly understood by those skilled in the art from descriptions below.

A transparent display apparatus according to an embodiment of the present disclosure may include a substrate including a display area and a non-display area, wherein the display area is provided with a transmission area and a non-transmission area including an emission area in which a light emitting element is disposed, and the non-display area is provided in a periphery of the display area, at least one power line disposed in the non-transmission area of the display area on the substrate and configured to extend in a first direction, a power shorting bar disposed in the non-display area on the substrate, electrically connected to the at least one power line, and extending in a second direction transverse to the first direction, and at least one undercut line disposed in the display area and the non-display area on the substrate and extending in the first direction.

According to the embodiment of the present disclosure, it is possible to provide the transparent display apparatus capable of reducing the occurrence of defects caused by the moisture penetration.

According to the embodiment of the present disclosure, it is possible to provide the transparent display apparatus capable of preventing the degradation of process reliability by the formation of moisture permeation preventing structure.

According to the embodiment of the present disclosure, it is possible to provide the transparent display apparatus being manufactured in various types (or various sizes).

The transparent display apparatus according to one or more embodiments of the present disclosure may reduce the manufacturing process for producing various types of transparent display apparatus by cutting the large-sized transparent display panel into various types (or various sizes) through the use of cutting process so that it is possible to reduce the generation of greenhouse gases, which might occur due to the manufacturing process, to thereby implement Environment/Social/Governance ESG.

The effects of the present disclosure are not limited to the aforesaid, but other effects not described herein will be clearly understood by those skilled in the art from descriptions below.

The details of the present disclosure described in technical problem, technical solution, and advantageous effects do not specify essential features of claims, and thus, the scope of claims is not limited by the details described in detailed description of the disclosure.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 illustrates a transparent display apparatus according to an embodiment of the present disclosure.

FIG. 2 is a circuit diagram of a subpixel of a transparent display apparatus according to an embodiment of the present disclosure.

FIG. 3 illustrates a region A shown in FIG. 1 according to an embodiment of the present disclosure.

FIG. 4 illustrates a region B shown in FIG. 3 according to one embodiment of the present disclosure.

FIG. 5 is a cross-sectional view along I-I′ of FIG. 4 according to one embodiment of the present disclosure.

FIG. 6 is a cross-sectional view along II-II′ of FIG. 4 according to one embodiment of the present disclosure.

FIG. 7 illustrates a transparent display apparatus according to another embodiment of the present disclosure.

FIG. 8 illustrates a transparent display apparatus according to another embodiment of the present disclosure.

FIG. 9 illustrates a region C shown in FIG. 7 according to another embodiment of the present disclosure.

FIG. 10 is a cross-sectional view along III-III′ of FIG. 9 according to another embodiment of the present disclosure.

FIG. 11 is a cross-sectional view along IV-IV′ of FIG. 9 according to another embodiment of the present disclosure.

FIG. 12 illustrates a region C shown in FIG. 7 according to another embodiment of the present disclosure.

FIG. 13 is a cross-sectional view along V-V′ of FIG. 12 according to another embodiment of the present disclosure.

FIG. 14 illustrates a region C shown in FIG. 7 according to another embodiment of the present disclosure.

FIG. 15 is a cross-sectional view along VI-VI′ of FIG. 14 according to another embodiment of the present disclosure.

FIG. 16 illustrates a transparent display apparatus according to another embodiment of the present disclosure.

FIG. 17 illustrates a transparent display apparatus according to another embodiment of the present disclosure.

Throughout the drawings and the detailed description, unless otherwise described, the same drawing reference numerals should be understood to refer to the same elements, features, and structures.

### DETAILED DESCRIPTION

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete, to assist those skilled in the art to understand the inventive concepts without limiting the protected scope of the present disclosure.

Shapes (e.g., sizes, lengths, widths, heights, thicknesses, locations, radii, diameters, and areas), sizes, ratios, angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term “comprise,” “have,” “include,” “contain,” “constitute,” “made of,” “formed of,” or the like is used with respect to one or more elements, one or more other elements may be added unless a term such as “only” or the like is used. The terms used in the present disclosure are merely used in order to describe example embodiments, and are not intended to limit the scope of the present disclosure. The terms of a singular form may include plural forms unless the context clearly indicates otherwise.

In construing an element, the element is construed as including an error region although there is no explicit description thereof.

In describing a positional relationship, for example, when the positional order is described as “on,” “above,” “below,” “beneath,” and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element is “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The term “at least one” should be understood as including any and all combinations of one or more of the associated listed items. For example, “at least one among a first element, a second element and a third element” may include all combinations of two or more elements selected from the first, second and third elements as well as each element of the first, second and third elements.

Features of various embodiments of the present disclosure may be partially or entirety coupled to or combined with each other, may be technically associated with each other, and may be variously inter-operated, linked or driven together. The embodiments of the present disclosure may be implemented or carried out independently of each other, or may be implemented or carried out together in a co-dependent or related relationship. In one or more aspects, the components of each apparatus according to various embodiments of the present disclosure are operatively coupled and configured.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

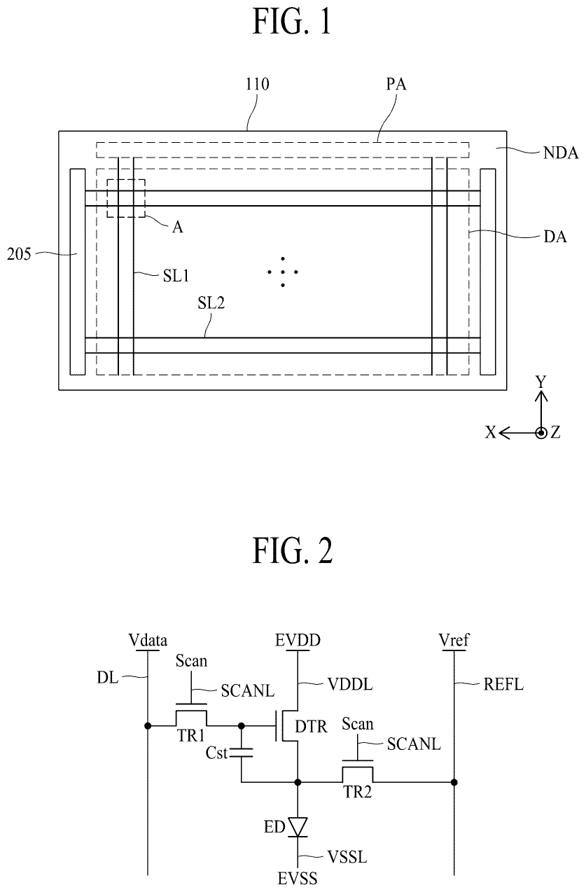

FIG. 1 illustrates a transparent display apparatus according to an embodiment of the present disclosure. FIG. 2 is a circuit diagram of a subpixel of the transparent display apparatus according to the embodiment of the present disclosure.

Hereinafter, an X-axis represents a direction parallel to a scan line, a Y-axis represents a direction parallel to a data line, and a Z-axis represents a height direction of the transparent display apparatus.

The transparent display apparatus according to one embodiment of the present disclosure is implemented as an organic light emitting display OLED. However, it may be implemented as a liquid crystal display LCD device, a micro light emitting diode Micro LED Display, a quantum dot Display QD, or the like.

Referring to FIGS. 1 and 2, the transparent display apparatus according to one embodiment of the present disclosure may include a transparent display panel 110 having a display area DA and a non-display area NDA, wherein the display area DA is provided with pixels to display an image and an image is not displayed on the non-display area NDA. The non-display area NDA is configured to be in the vicinity of the display area DA, partially or fully surround the display area DA.

The display area DA of the transparent display panel 110 may include first signal lines SL1, second signal lines SL2, and pixels, and the non-display area NDA may include a pad area PA in which pads are disposed and at least one gate driver 205.

The first signal lines SL1 may extend in a first direction (or Y-axis direction), and may intersect the second signal lines SL2 in the display area DA. The second signal lines SL2 may extend in a second direction (or X-axis direction). The pixels are disposed in a region where the first signal line SL1 and the second signal line SL2 cross each other, and may emit a predetermined light to display an image.

The gate driver 205 may be connected to a scan line to supply a scan signal. The gate driver 205 may be implemented in a gate driver in panel GIP type or a tape automated bonding TAB type in the non-display area NDA on one side or both sides of the display area DA of the transparent display panel 110.

A source drive integrated circuit, a circuit board, or a timing controller connected through a flexible circuit film may be electrically connected to the pad area PA of the transparent display panel 110.

Referring to FIG. 2, each of the pixels includes a plurality of subpixels constituting a unit pixel. In each of the plurality of subpixels, there are a circuit element having 3T(Transistor)1C(Capacitor) including a first switching transistor TR1, a second switching transistor TR2, a driving transistor DTR and a capacitor Cst, and a light emitting element ED, but not limited thereto. Each subpixel may further include a compensation circuit. In this case, the subpixel may have various structures such as 4T2C, 5T2C, 6T1C, 6T2C, 7T1C, and 7T2C.

Each of the transistors DTR, TR1, and TR2 of each subpixel may include a gate electrode, a source electrode, and a drain electrode. According as the source electrode and the drain electrode may be changed according to a voltage applied to the gate electrode and a current direction without being fixed, any one of the source electrode and the drain electrode may be represented as a first electrode, and the other may be represented as a second electrode. The transistors DTR, TR1, and TR2 of each subpixel may use at least one of polysilicon semiconductor, amorphous silicon semiconductor, and oxide semiconductor. The transistors DTR, TR1, and TR2 may be P-type or N-type, or P-type and N-type may be interchangeably used.

The first switching transistor TR1 may serve to supply a data voltage Vdata supplied from the data line DL to the driving transistor DTR. For example, the first switching transistor TR1 may charge the data voltage Vdata supplied from the data line DL to the capacitor Cst. To this end, the gate electrode of the first switching transistor TR1 is connected to the scan line SCANL (or gate line), and the first electrode thereof is connected to the data line DL. In addition, the second electrode of the first switching transistor TR1 may be connected to one end of the capacitor Cst and the gate electrode of the driving transistor DTR.

The first switching transistor TR1 may be turned-on in response to the scan signal applied through the scan line SCANL (or gate line). When the first switching transistor TR1 is turned-on, the data voltage Vdata applied through the data line DL may be transferred to one end of the capacitor Cst.

The second switching transistor TR2 may serve to supply a reference voltage Vref supplied from a reference line REFL to the driving transistor DTR. For example, the gate electrode of the second switching transistor TR2 is connected to the scan line (or gate line), and the first electrode thereof is connected to the reference line. In addition, the second electrode of the second switching transistor TR2 may be connected to the first electrode of the driving transistor DTR and the other end of the capacitor Cst.

The second switching transistor TR2 may be turned-on in response to the scan signal applied through the scan line (or gate line). When the second switching transistor TR2 is turned-on, the reference voltage Vref applied through the reference line REFL may be transferred to the other end of the capacitor Cst. In addition, the reference voltage Vref may also be applied to the source electrode of the driving transistor DTR.

The capacitor Cst maintains the data voltage Vdata supplied to the driving transistor DTR for one frame. For example, the first electrode of the capacitor Cst may be connected to the gate electrode of the driving transistor DTR, and the second electrode of the capacitor Cst may be connected to the source electrode of the driving transistor DTR. The capacitor Cst may store a voltage corresponding to the data voltage Vdata transferred through the first switching transistor TR1, and may turn on the driving transistor DTR with the stored voltage.

The driving transistor DTR may generate a data current from a first power source EVDD supplied from a pixel power line VDDL and may supply the data current to an anode electrode of the light emitting element ED. For example, the gate electrode of the driving transistor DTR may be connected to one end of the capacitor Cst, and the first electrode of the driving transistor DTR may be connected to the pixel power line VDDL. In addition, the second electrode of the driving transistor DTR may be connected to the anode electrode of the light emitting element ED.

The light emitting element ED may include an anode electrode connected to the driving transistor DTR, a cathode electrode suppled with a second power source EVSS from a common power line VSSL (or second power line), and a light emitting layer between the anode electrode and the cathode electrode. The anode electrode is an independent electrode for each light emitting element, however, the cathode electrode may be a common electrode shared by the entire light emitting elements. When a driving current is supplied from the driving transistor DTR to the light emitting element ED, electrons from the cathode electrode are injected into the light emitting layer of the light emitting element ED, and holes from the anode electrode are injected into the light emitting layer of the light emitting element ED, whereby fluorescent or phosphorescent materials emit by a recombination of the electrons and holes in the light emitting layer, thereby generating light of brightness proportional to a current value of the driving current.

The anode electrode of the light emitting element ED is connected to the second electrode of the driving transistor DTR, and the cathode electrode of the light emitting element ED is connected to the common power line VSSL. The light emitting element ED may emit light in response to the driving current generated by the driving transistor DTR.

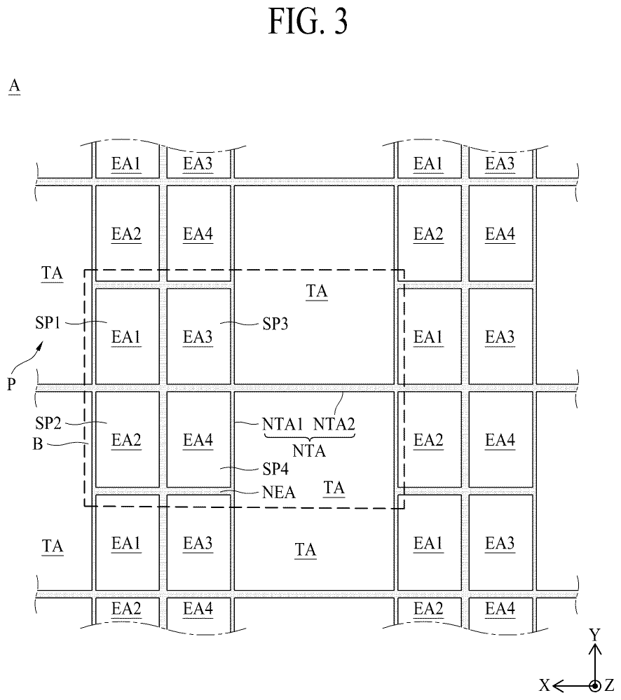

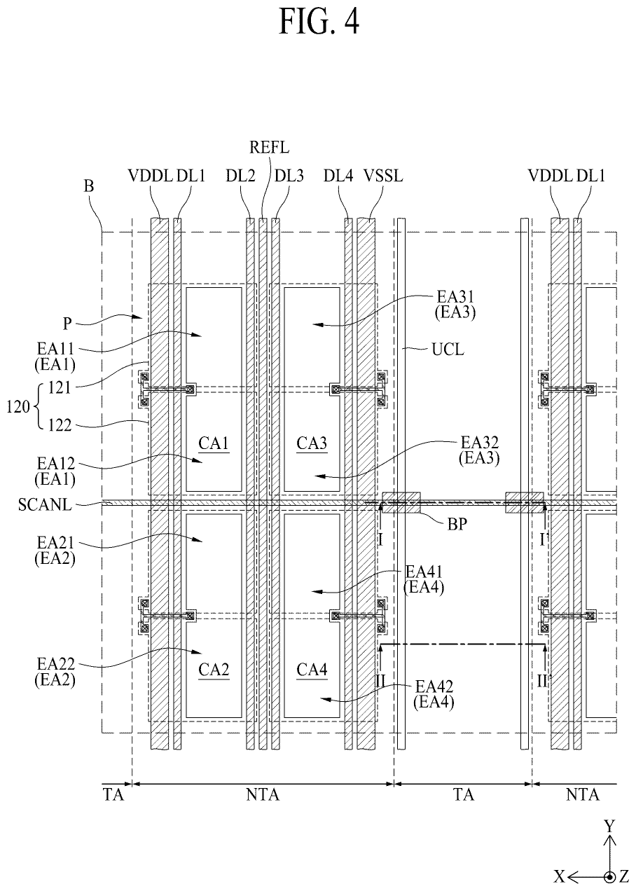

FIG. 3 illustrates a region A shown in FIG. 1 according to an embodiment of the present disclosure. FIG. 4 illustrates a region B shown in FIG. 3 according to one embodiment of the present disclosure.

Referring to FIGS. 3 and 4 in connection with FIGS. 1 and 2, a transparent display panel 110 according to an embodiment of the present disclosure may include a display area DA and a non-display area NDA. The display area DA may include a transmission area TA and a non-transmission area NTA. The transmission area TA may be an area through which most of light incident from the outside passes, and the non-transmission area NTA may be an area which does not transmit most of light incident from the outside. For example, the transmission area TA may be an area in which a light transmittance is greater than a %, and the non-transmission area NTA may be an area in which a light transmittance is less than b %. Herein, ‘a’ may be a value greater than ‘b.’ The transparent display panel 110 enables a user to see an object or background located on a rear surface of the transparent display panel 110 owing to the transmission areas TA.

A first non-transmission area NTA1, a second non-transmission area NTA2, and pixels P may be included in the non-transmission area NTA.

The first non-transmission area NTA1 may extend in the first direction (or Y-axis direction) on the display area DA, and may be disposed to at least partially overlap emission areas EA1, EA2, EA3, and EA4. There may be the plurality of first non-transmission area NTA1. The plurality of first non-transmission areas NTA1 may extend in the first direction (or Y-axis direction) and may be spaced apart from each other in the second direction (or X-axis direction). The two adjacent first non-transmission areas NTA1 may be arranged to be spaced apart from each other with the transmission area TA interposed therebetween. For example, the transmission area TA may be arranged between the two adjacent first non-transmission areas NTA1. The first signal lines SL1 extending in the first direction (or Y-axis direction) may be disposed in the first non-transmission area NTA1. For example, the first signal lines SL1 may be disposed to overlap the first non-transmission area NTA1.

The first signal lines SL1 may include at least one of the pixel power line VDDL (or first power line), the common power line VSSL (or second power line), the reference line REFL, and the data lines DL1, DL2, DL3, and DL4. For example, the first signal lines SL1 may further include a touch sensor line TL, but embodiments of the present disclosure are not limited thereto.

The pixel power line VDDL may supply a first power source EVDD to the driving transistor DTR of each of the subpixels SP1, SP2, S3, and SP4 provided in the display area DA. The pixel power line VDDL may be disposed on the right side or left side of the emission areas EA1, EA2, EA3, and EA4. For example, the pixel power line VDDL may be disposed on the right side of the emission area EA1, EA2, EA3, and EA4, alternatively, the pixel power line VDDL may be disposed on the left side of the emission area EA1, EA2, EA3, and EA4, but embodiments of the present disclosure are not limited thereto.

The common power line VSSL may supply the second power source EVSS to the cathode electrode of the subpixels SP1, SP2, SP3, and SP4 provided in the display area DA. In this case, the second power source EVSS may be a common power source commonly supplied to the subpixels SP1, SP2, SP3, and SP4. The common power line VSSL may be disposed on the right side or left side of the emission areas EA1, EA2, EA3, and EA4. For example, the common power line VSSL may be disposed on the left side of the emission area EA1, EA2, EA3, and EA4, alternatively, the common power line VSSL may be disposed on the right side of the emission area EA1, EA2, EA3, and EA4, but embodiments of the present disclosure are not limited thereto.

The reference line REFL may supply an initialization voltage (or reference voltage) to the driving transistor DTR of each of the subpixels SP1, SP2, SP3, and SP4 provided in the display area DA. For example, the reference line REFL may be disposed between the plurality of data lines DL1, DL2, DL3, and DL4. For example, the reference line REFL may be disposed in the middle of the plurality of data lines DL1, DL2, DL3, and DL4.

Each of the data lines DL1, DL2, DL3, and DL4 may supply the data voltage Vdata to the subpixels SP1, SP2, SP3, and SP4. For example, the first data line DL1 supplies the first data voltage to the first driving transistor of the first subpixel SP1, the second data line DL2 supplies the second data voltage to the second driving transistor of the second subpixel SP2, the third data line DL3 supplies the third data voltage to the third driving transistor of the third subpixel SP3, and the fourth data line DL4 supplies the fourth data voltage to the fourth driving transistor of the fourth subpixel SP4.

The second non-transmission area NTA2 may extend in the second direction (or X-axis direction) on the display area DA, and may be disposed to at least partially overlap the emission areas EA1, EA2, EA3, and EA4. For example, the second non-transmission area NTA2 may extend in the second direction (or X-axis direction) between the two adjacent first non-transmission areas NTA1. There may be the plurality of second non-transmission areas NTA2. The plurality of second non-transmission areas NTA2 may extend in the second direction (or X-side direction) and may be spaced apart from each other in the first direction (or Y-axis direction). The two adjacent second non-transmission areas NTA2 may be arranged to be spaced apart from each other with the transmission area TA interposed therebetween. For example, the transmission area TA may be arranged between the two adjacent second non-transmission areas NTA2. The second signal lines SL2 extending in the second direction (or X-axis direction) may be disposed in the second non-transmission area NTA2. For example, the second signal lines SL2 may be disposed to overlap the second non-transmission area NTA2.

The second signal lines SL2 extend in the second direction (or X-axis direction) and include the scan line (or gate line). The scan line may supply the scan signal to the subpixels SP1, SP2, SP3, and SP4 of the pixel P.

The scan line SCANL may be connected to the respective pixels P corresponding to a horizontal line in which the plurality of pixels P are arranged in parallel in the second direction (or X-axis direction). The scan line SCANL may be disposed in the center of the pixels P corresponding to the horizontal line. For example, the scan line SCANL may be disposed between the first and third subpixels SP1 and SP3 of each pixel P and the second and fourth subpixels SP2 and SP4 of each pixel P. Alternatively, the scan line SCANL may be disposed at an upper side or lower side of the pixels P corresponding to the horizontal line. For example, the scan line SCANL may be disposed at the upper side of the first and third subpixels SP1 and SP3 of the pixels P corresponding to the horizontal line, or may be disposed at the lower side of the second and fourth subpixels SP2 and SP4 of the pixels P corresponding to the horizontal line, but embodiments of the present disclosure are not limited thereto.

The pixels P may be arranged in each crossing area where the first non-transmission area NTA1 and the second non-transmission area NTA2 cross each other, and may emit light to display an image. Each of the pixels P is disposed between the adjacent transmission areas TA, and the pixel P may include the emission areas EA1, EA2, EA3, and EA4 in which the light emitting element is disposed to emit light. The emission area EA1, EA2, EA3, and EA4 may correspond to an area in which light is emitted from the pixel P. Since the area of the non-transmission area NTA is small, the circuit element may be disposed to overlap the emission areas EA1, EA2, EA3, and EA4 in the transparent display panel 110. For example, the emission areas EA1, EA2, EA3, and EA4 may at least partially overlap the circuit areas CA1, CA2, CA3, and CA4 in which the circuit elements are disposed. For example, the circuit area CA1, CA2, CA3, and CA4 may include the first circuit area CA1 in which the circuit element connected to the first subpixel SP1 is disposed, the second circuit area CA2 in which the circuit element connected to the second subpixel SP2 is disposed, the third circuit area CA3 in which the circuit element connected to the third subpixel SP3 is disposed, and the fourth circuit area CA4 in which the circuit element connected to the fourth subpixel SP4 is disposed.

Each of the pixels P may be provided in the first non-transmission area NTA 1, and may emit light to display an image. Each of the pixels P may include the first subpixel SP1, the second subpixel SP2, the third subpixel SP3, and the fourth subpixel SP4. The first subpixel SP1 may include the first emission area EA1 for emitting a first color light, the second subpixel SP2 may include the second emission area EA2 for emitting a second color light, the third subpixel SP3 may include the third emission area EA3 for emitting a third color light, and the fourth subpixel SP4 may include the fourth emission area EA4 for emitting a fourth color light.

All the first to fourth emission areas EA1, EA2, EA3, and EA4 may respectively emit light of different colors. For example, the first emission area EA1 may emit green light, the second emission area EA2 may emit blue light, the third emission area EA3 may emit white light, and the fourth emission area EA4 may emit red light, but not limited thereto. In addition, the arrangement order or arrangement of each of the subpixels SP1, SP2, SP3, and SP4 may be variously changed.

The first to fourth subpixels SP1, SP2, SP3, and SP4 may be arranged in a quad-type matrix along the first direction (or Y-axis direction) and the second direction (or X-axis direction). The first to fourth subpixels SP1, SP2, SP3, and SP4 may be disposed adjacent to the pixel power line VDDL (or first power line) or the common power line VSSL (or second power line). For example, the first and second subpixels SP1 and SP2 may be disposed adjacent to the common power line VSSL, and the third and fourth subpixels SP3 and SP4 may be disposed adjacent to the pixel power line VDDL, alternatively, the first and second subpixels SP1 and SP2 may be disposed adjacent to the pixel power line VDDL, and the third and fourth subpixels SP3 and SP4 may be disposed adjacent to common power line VSSL, but embodiments of the present disclosure are not limited thereto.

Referring to FIG. 4, the transparent display panel 110 according to an embodiment of the present disclosure may include light-emitting areas formed by dividing the emission areas EA1, EA2, EA3, and EA4 included in each of the plurality of subpixels SP1, SP2, SP3, and SP4. For example, each of the plurality of subpixels SP1, SP2, SP3, and SP4 may include a first divided electrode 121 and a second divided electrode 122 which are formed by separating a first electrode 120 (or anode electrode) of the light emitting element while being spaced apart from each other. Each of the first divided electrode 121 and the second divided electrode 122 may correspond to the divided light-emitting area. For example, the first emission area EA1, EA2, EA3, and EA4 included in each of the subpixels SP1, SP2, SP3, and SP4 may include the first divided light-emitting area EA11, EA21, EA31, and EA41 and the second divided light-emitting area EA12, EA22, EA32, and EA42 which correspond to the first divided electrode 121 and the second divided electrode 122, respectively. When a foreign substance is generated in any one of the first divided electrode 121 and the second divided electrode 122 according to an embodiment of the present disclosure, the divided electrode with the foreign substance is electrically separated or disconnected from the circuit area CA1, CA2, CA3, and CA4, so that only the electrode with the foreign substance may be darkened, and the remaining divided electrode may be repaired to be normally operated.

As shown in FIG. 2, the pixel circuits CA1, CA2, CA3, and CA4 of each of the plurality of subpixels SP1, SP2, SP3, and SP4 may include a capacitor Cst, at least one thin film transistor DRT, TR1, and TR2, and a light emitting element ED. For example, the at least one thin film transistor DRT, TR1, and TR2 may include a driving transistor DTR, a first switching transistor TR1, and a second switching transistor TR2. In addition, the light emitting element ED may include a first electrode (or anode electrode, pixel electrode), a light emitting layer (or organic light emitting layer), and a second electrode (or cathode electrode, common electrode). However, the pixel circuits CA1, CA2, CA3, and CA4 of each of the plurality of subpixels SP1, SP2, SP3, and SP4 are not limited thereto, each of the plurality of subpixels SP1, SP2, SP3, and SP4 may further include a compensation circuit. In this case, each of the plurality of subpixels SP1, SP2, SP3, and SP4 may have various structures such as 4T2C, 5T2C, 6T1C, 6T2C, 7T1C, 7T2C, and the like.

The transparent display panel 110 according to an embodiment of the present disclosure may further include at least one undercut line UCL extending in the first direction (or Y-axis direction) in the transmission area TA.

The at least one undercut line UCL may be disposed on one side (or left side) of the transmission area TA or may be disposed on the other side (or right side) of the transmission area TA. For example, the at least one undercut line UCL may be disposed in the transmission area TA and may be arranged adjacent to the common power line VSSL (or second power line) disposed in the non-transmission area NTA. Alternatively, the at least one undercut line UCL may be disposed in the transmission area TA and may be arranged adjacent to the pixel power line VDDL (or first power line) disposed in the non-transmission area NTA, but embodiments of the present disclosure are not limited thereto. For example, at least two undercut lines UCL may be disposed in the transmission area TA. The at least one undercut line UCL may be disposed on one side (or left side) of the transmission area TA and other undercut lines UCL may be disposed on the other side (or right side) of the transmission area TA.

The at least one undercut line UCL may serve to separate or disconnect the light emitting layer (or organic light emitting layer) disposed in the transmission area TA. The at least one undercut line UCL may be composed of at least a portion of an inorganic insulating layer (for example, passivation layer) and an organic insulating layer (for example, planarization layer). For example, the at least one undercut line UCL may be configured by removing at least a portion of the inorganic insulating layer (for example, passivation layer) and the organic insulating layer (for example, planarization layer).

The scan line (or gate line) crossing the transmission area TA may be disposed under the at least one undercut line UCL. A block pattern BP may be further included in a portion at which the at least one undercut line UCL and the scan line SCANL intersect. For example, in a process of forming the at least one undercut line UCL, the block pattern BP may prevent damages on the scan line SCANL crossing the at least one undercut line UCL disposed thereunder.

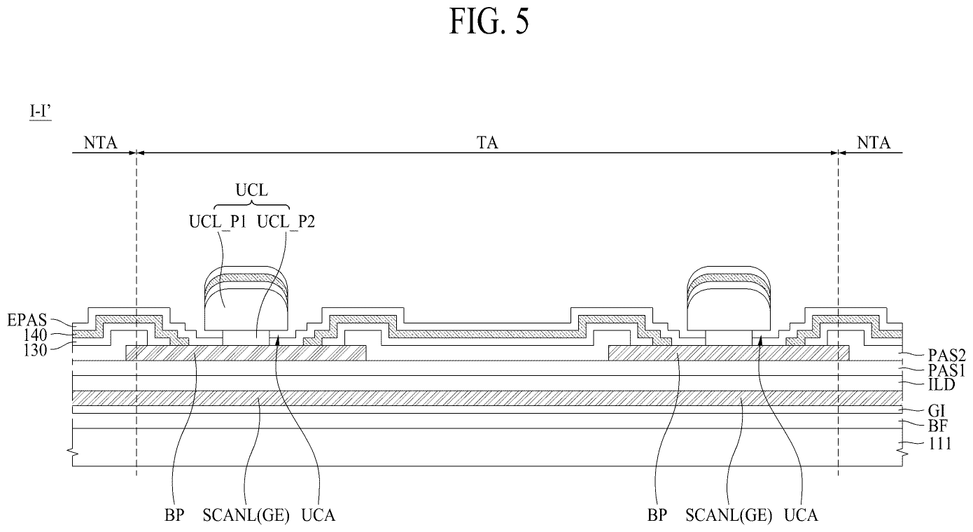

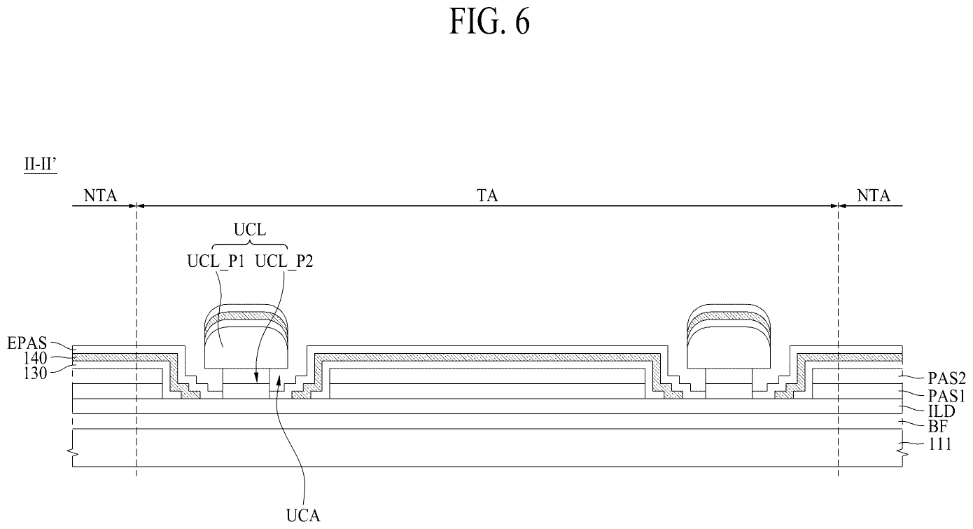

FIG. 5 is a cross-sectional view along I-I′ of FIG. 4 according to one embodiment of the present disclosure. FIG. 6 is a cross-sectional view along II-II′ of FIG. 4 according to one embodiment of the present disclosure.

Referring to FIGS. 5 and 6 in connection with FIG. 4, a buffer layer BF may be disposed on a substrate 111 of a transparent display panel 110 according to one embodiment of the present disclosure, and at least one insulating layer, a thin film transistor, and at least one signal line may be disposed on the buffer layer BF. For example, as shown in FIG. 5, a scan line SCANL(GE) (or gate line) may be disposed on the buffer layer BF. The scan line SCANL(GE) (or gate line) may be made of the same material as a gate electrode GE of the thin film transistor on the same layer. A gate insulating layer GI may be disposed between the scan line SCANL(GE) (or gate line) and the buffer layer BF.

An interlayer insulating layer ILD may be disposed on the buffer layer BF on which the scan line SCANL(GE) (or gate line) is disposed. The interlayer insulating layer ILD may be formed in a single-layered structure or a multi-layered structure including an inorganic insulating material such as silicon oxide SiO_{X}, silicon nitride SiN_{X}, aluminum oxide Al₂O₃, and the like.

A first passivation layer PAS1 may be disposed on the interlayer insulating layer ILD. A second passivation layer PAS2 may be disposed on the first passivation layer PAS1. The first passivation layer PAS1 and the second passivation layer PAS2 may be formed in a single-layered structure or a multi-layered structure including an inorganic insulating material such as silicon oxide SiO_{X}, silicon nitride SiN_{X}, aluminum oxide Al₂O₃, and the like.

A planarization layer PLN for planarizing a step difference due to the thin film transistor and the plurality of signal lines may be disposed on the second passivation layer PAS2. The planarization layer PLN may be formed of an organic material such as acryl resin, epoxy resin, phenolic resin, polyamide resin, polyimide resin, or the like. A first electrode, an organic light emitting layer 130, and a second electrode 140 of a light emitting element may be disposed on the planarization layer PLN. The light emitting elements may be arranged in a non-transmission area NTA on the substrate 111. An encapsulation layer EPAS may be disposed on the light emitting elements of the substrate 111. The encapsulation layer EPAS may be disposed on the second electrode 140 and may be configured to cover the second electrode 140. According to the embodiment of the present disclosure, a transparency of a transmission area TA be increased by removing most of the planarization layer PLN from the transmission area TA on the substrate 111 and providing the planarization layer PLN only in a portion of the transmission area TA on the substrate 111. For example, the organic light emitting layer 130 and the second electrode 140 extending from the light emitting elements may be disposed on the second passivation layer PAS2 in the transmission area TA of the substrate 111.

At least one undercut line UCL may be disposed in the transmission area TA on the substrate 111 according to the embodiment of the present disclosure. The at least one undercut line UCL may be arranged to extend in a first direction (or Y-axis direction) in the transmission area TA. For example, the at least one undercut line UCL may be configured by using at least a portion of the planarization layer PLN and the first and second passivation layers PAS1 and PAS2. The at least one undercut line UCL may serve to disconnect the organic light emitting layer 130 from the transmission area TA. For example, the at least one undercut line UCL may separate or disconnect the organic light emitting layer 130 extending from the non-transmission area NTA. Thus, the at least one undercut line UCL may block a moisture permeation path with respect to the boundary of at least one undercut line UCL.

Referring to FIG. 5, at least a portion of the at least one undercut line UCL may be disposed to overlap at least one scan line (or gate line) in the transmission area TA. The block pattern BP may be disposed at a portion where the at least one undercut line UCL and the at least one scan line SCANL overlap. The block pattern BP may be disposed on the first passivation layer PAS1. For example, the block pattern BP may prevent damages on the at least one scan line (or gate line) overlapping with the at least one undercut line UCL in a process of forming the at least one undercut line UCL.

The at least one undercut line UCL may be configured by using the planarization layer PLN and the second passivation layer PAS2. For example, the at least one undercut line UCL may be configured by removing at least a portion of the planarization layer PLN and the second passivation layer PAS2. The at least one undercut line UCL may include a first pattern line UCL_P1 formed of the same material as the planarization layer PLN and a second pattern line UCL_P2 composed of the second passivation layer PAS2. For example, the first pattern line UCL_P1 of the at least one undercut line UCL may be formed by patterning the planarization layer PLN, and the second pattern line UCL_P2 of the at least one undercut line UCL may be formed by removing at least a portion of the second passivation layer PAS2 to have an undercut area UCA under the first pattern line UCL_P1.

Referring to FIG. 6, at least a portion of the at least one undercut line UCL may be disposed not to overlap with other signal lines in the transmission area TA.

The at least one undercut line UCL may be configured by using the planarization layer PLN and the first and second passivation layers PAS1 and PAS2. For example, the at least one undercut line UCL may be configured by removing at least a portion of the planarization layer PLN and the first and second passivation layers PAS1 and PAS2. The at least one undercut line UCL may include a first pattern line UCL_P1 formed of the same material as the planarization layer PLN and a second pattern line UCL_P2 composed of the first and second passivation layers PAS1 and PAS2. For example, the first pattern line UCL_P1 of the at least one undercut line UCL may be formed by patterning the planarization layer PLN, and the second pattern line UCL P2 of the at least one undercut line UCL may be formed by removing at least a portion of the first and second passivation layers PAS1 and PAS2 to have an undercut area UCA under the first pattern line UCL_P1.

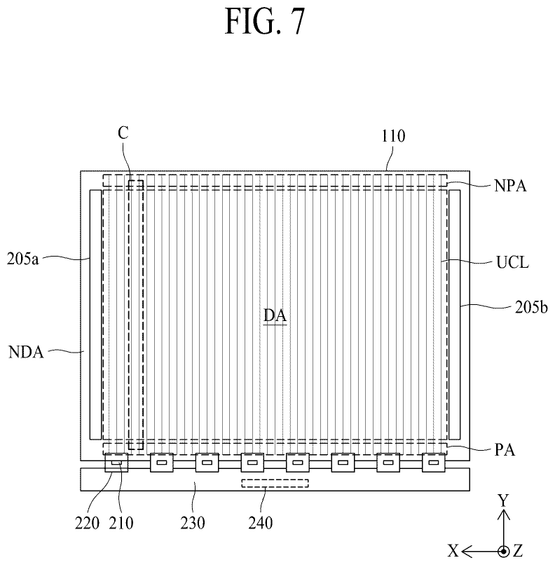

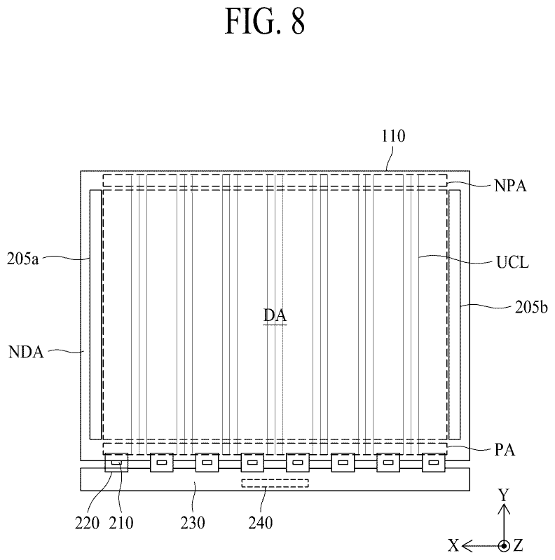

FIG. 7 illustrates a transparent display apparatus according to another embodiment of the present disclosure. FIG. 8 illustrates a transparent display apparatus according to another embodiment of the present disclosure.

Referring to FIGS. 7 and 8, a transparent display panel 110 according to another embodiment of the present disclosure may include a display area DA in which pixels are configured to display an image and a non-display area NDA that does not display an image. For example, the non-display area NDA may be disposed in the periphery of the display area DA.

As shown in FIGS. 3 and 4, the plurality of pixels P including a plurality of subpixels SP1, SP2, SP3, and SP4 and a transmission area TA may be disposed in the display area DA of the transparent display panel 110. The transparent display panel 110 may include at least one undercut line UCL extending in a first direction (or Y-axis direction) in the transmission area TA of the display area DA of the transparent display panel 110.

The non-display area NDA of the transparent display panel 110 may include a pad area PA having pads to which external signals are applied and a plurality of gate drivers 205a and 205b. Also, the transparent display panel 110 may include a non-pad area NPA disposed in the non-display area NDA facing the pad area PA with the display area DA interposed therebetween. For example, the non-pad area NPA may be disposed in an area opposite to the pad area PA in the non-display area NDA of the transparent display panel 110. The non-pad area NPA may be an area in which the pads are not disposed.

At least one undercut line UCL according to another embodiment of the present disclosure may be disposed in the non-display area NDA and the display area DA. For example, the at least one undercut line UCL may be arranged to extend in the first direction (or Y-axis direction) in the non-display area NDA and the display area DA. For example, the at least one undercut line UCL may extend from the non-display area NDA to the display area DA. In at least a portion of the non-display area NDA, an organic light emitting layer constituting a light emitting element may be disposed to extend from the display area DA, and the at least one undercut line UCL may extend from a portion where the organic light emitting layer is disposed in the non-display area NDA to the display area DA. For example, the at least one undercut line UCL may extend from the pad area PA of the non-display area NDA to cross the display area DA and may extend to the non-pad area NPA of the non-display area NDA. For example, the at least one undercut line UCL may extend from the pad area PA of the non-display area NDA to cross the display area DA and may extend to the non-pad area NPA of the non-display area NDA in the first direction (or Y-axis direction), however, the present disclosure is not limited thereto.

At least one power shorting bar may be disposed in the non-display area NDA of the transparent display panel 110. The at least one power shorting bar is electrically connected to at least one power line disposed in the display area DA and may be arranged to extend in a second direction (or X-axis direction) in the non-display area NDA. At least one undercut line UCL according to another embodiment of the present disclosure may overlap at least one power shorting bar in the non-display area NDA. For example, the at least one undercut line UCL may intersect and overlap with the at least one power shorting bar in the non-display area NDA.

A flexible film 220 may be connected to the pad area PA of the non-display area NDA of the transparent display panel 110 in a tape automated bonding TAB method, and a source drive integrated circuit 210 (hereinafter, referred to as “IC”), a circuit board 230, and a timing controller 240 connected through the flexible film 220 may be electrically connected to the pad area PA.

Referring to FIG. 7, the at least one undercut line UCL may include the plurality of undercut lines UCL provided in parallel with the first direction (or Y-axis direction) in the display area DA and spaced apart from each other in the second direction (or X-axis direction). Each of the plurality of undercut lines UCL may be arranged to be spaced apart from each other at predetermined intervals in the second direction (or X-axis direction). For example, the plurality of undercut lines UCL may be uniformly disposed on the entire surface of the non-display area NDA and the display area DA. For example, each of the plurality of undercut lines UCL may extend from the pad area PA of the non-display area NDA to cross the display area DA and may extend to the non-pad area NPA of the non-display area NDA in the first direction (or Y-axis direction), however, the present disclosure is not limited thereto.

Referring to FIG. 8, the plurality of undercut lines UCL may be disposed to be concentrated on a portion of the non-display area NDA and the display area DA. For example, the plurality of undercut lines UCL may be disposed not to overlap the flexible film 220 in the pad area PA of the non-display area NDA. The plurality of undercut lines UCL may be disposed not to overlap a portion where the flexible film 220 is connected by a tape automated bonding TAB method in the pad area PA of the non-display area NDA. For example, the plurality of undercut lines UCL may be disposed between the adjacent flexible films 220 in the pad area PA of the non-display area NDA. The plurality of undercut lines UCL may be arranged to be spaced apart from each other at predetermined intervals in the second direction (or X-axis direction) between the adjacent flexible films 220.

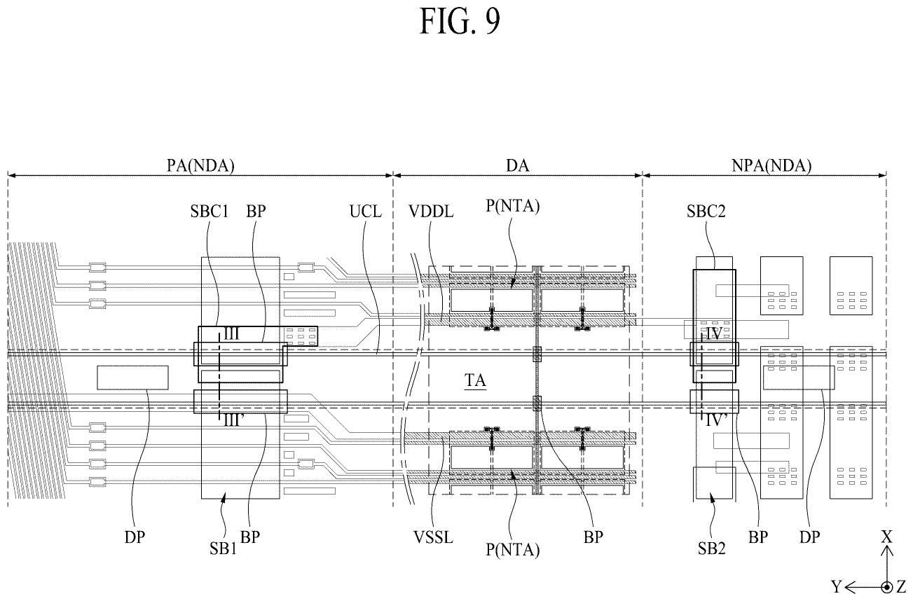

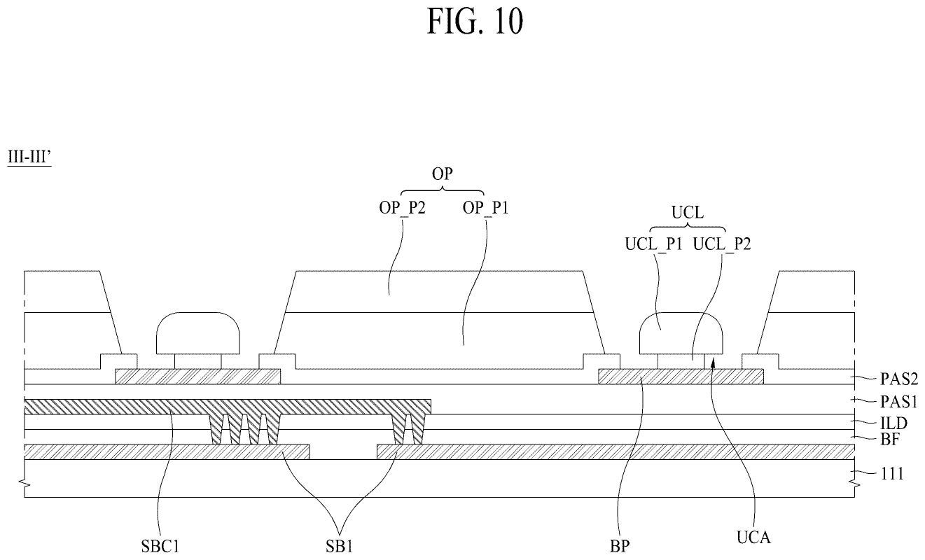

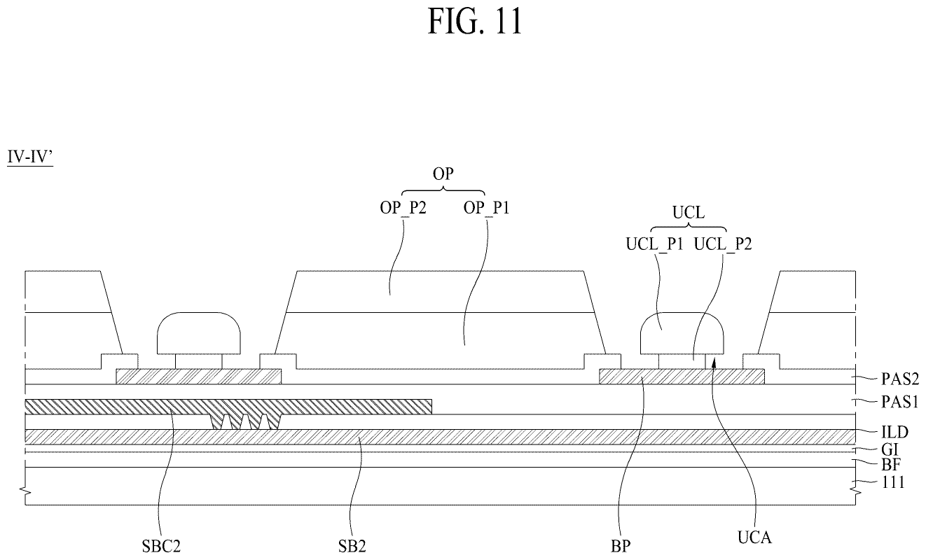

FIG. 9 illustrates a region C shown in FIG. 7 according to another embodiment of the present disclosure. FIG. 10 is a cross-sectional view along III-III′ of FIG. 9 according to another embodiment of the present disclosure. FIG. 11 is a cross-sectional view along IV-IV′ of FIG. 9 according to another embodiment of the present disclosure.

Referring to FIGS. 9 to 11, in a transparent display panel 110 according to another embodiment of the present disclosure, at least one undercut line UCL may be disposed in a non-display area NDA and a display area DA. The at least one undercut line UCL may be disposed to extend in a first direction (or Y-axis direction) in a transmission area TA of each of pixels P disposed in the display area DA. The at least one undercut line UCL may be disposed on one side and the other side in a second direction (or X-axis direction) in the transmission area TA.

The at least one undercut line UCL may have a portion disposed in the display area DA and a portion disposed in the non-display area NDA, wherein the portions respectively disposed in the display area DA and the non-display area NDA may be arranged in the same line along the first direction (or Y-axis direction). For example, the at least one undercut line UCL may extend from a pad area PA of the non-display area NDA to a non-pad area NPA of the non-display area NDA while crossing the transmission area TA of the display area DA from the pad area PA of the non-display area NDA in the same line along the first direction (or Y-axis direction).

At least one power shorting bar SB1 and SB2 may be disposed in the non-display area NDA of the transparent display panel 110. The at least one power shorting bar SB1 and SB2 may be arranged to extend in the second direction (or X-axis direction) in the non-display area NDA. For example, the at least one power shorting bar SB1 and SB2 may be electrically connected to a pixel power line VDDL (or first power line) and a common power line VSSL (or second power line) of each of the pixels P disposed in the display area DA. For example, as shown in FIG. 9, the at least one power shorting bar SB1 and SB2 may be connected to the pixel power line VDDL of each pixel P. The at least one power shorting bar SB1 and SB2 may include a power line contact portion SBC1 and SBC2 connected to the pixel power line VDDL of each pixel P. For example, the at least one power shorting bar SB1 and SB2 may be formed of a different metal layer in a different layer from that of the power line contact portion SBC1 and SBC2. For example, the at least one power shorting bar SB1 and SB2 may be formed on a substrate 111, the power line contact portions SBC1 and SBC2 are formed on insulating layers over the at least one power shorting bar SB1 and SB2, and electrically connect to the at least one power shorting bar SB1 and SB2 through contact holes in the insulating layers, however, the present disclosure is not limited thereto.

The non-display area NDA of the transparent display panel 110 may further include a dummy electrode pattern DP disposed in the periphery of the at least one undercut line UCL. For example, the dummy electrode pattern DP may be disposed around one side or the other side of the at least one undercut line UCL. Alternatively, the dummy electrode pattern DP may be disposed between the plurality of adjacent undercut lines UCL, but embodiments of the present disclosure are not limited thereto.

In a process of forming the undercut area UCL extending from the non-display area NDA to the display area DA, the dummy electrode pattern DP may prevent an etching deviation caused by an etchant from occurring between the display area DA in which a first electrode (or pixel electrode) constituting a light emitting element is patterned and the non-display area NDA in which the first electrode is not patterned. For example, the dummy electrode pattern DP may be made of the same material as the first electrode (or pixel electrode) constituting the light emitting element, and may prevent over-etching in the non-display area NDA when forming the undercut line UCL, thereby improving uniformity of the undercut line UC formed in the non-display area NDA and the display area DA.

Referring to FIG. 10, the at least one power shorting bar SB1 may be disposed in the pad area PA of the non-display area NDA on a substrate 111. The at least one power shorting bar SB1 may extend in the second direction (or X-axis direction) in the pad area PA. The at least one power shorting bar SB1 may be disposed to intersect and overlap the at least one undercut line UCL in the pad area PA.

The at least one power shorting bar SB1 may be disposed in the pad area PA on the substrate 111. For example, the at least one power shorting bar SB1 may be a pixel power shorting bar SB1 connected to the pixel power line VDDL (or first power line) extending in the first direction (or Y-axis direction) in the display area DA and configured to supply a first power. Also, a light shielding layer may be disposed on the substrate 111. For example, the light shielding layer may serve to block external light incident to an active layer of the thin film transistor. The light shielding layer may be formed in a single-layered structure or multi-layered structure of molybdenum Mo, aluminum Al, chromium Cr, gold Au, titanium Ti, nickel Ni, neodymium Nd, and copper Cu, or an alloy thereof. The at least one power shorting bar SB1 may be formed of the same material on the same layer as the light shielding layer, but embodiments of the present disclosure are not limited thereto. For example, the at least one power shorting bar SB1 may be formed of a different material from the light shielding layer.

The at least one power shorting bar SB1 in the pad area PA on the substrate 111 may be partially spaced apart for the connection with another component in some sections. The at least one power shorting bar SB1 may include portions having different shapes on the substrate 111. For example, the at least one power shorting bar SB1 may be configured to have a plurality of slit structures to reduce electrical effects with other signal lines. For example, the at least one power shorting bar SB1 may be configured to have the plurality of slit structures in a portion overlapping a data line DL, a reference line REFL, and the common power line VSSL or the like. The at least one power shorting bar SB1 may include a contact portion electrically connected to the pixel power line VDDL extending in the first direction (or Y-axis direction) in the display area DA.

A buffer layer BF may be disposed on the substrate 111 on which the at least one power shorting bar SB1 and the light shielding layer are disposed. The buffer layer BF protects the thin film transistor from moisture penetrating through the substrate 111 vulnerable to moisture permeation. The buffer layer BF may be formed in a single-layered structure or a multi-layered structure including an inorganic insulating material such as silicon oxide SiO_{X}, silicon nitride SiN_{X}, aluminum oxide Al₂O₃, and the like.

At least one insulating layer, a thin film transistor, and at least one signal line may be disposed on the buffer layer BF. For example, an interlayer insulating layer ILD may be disposed on the buffer layer BF. The interlayer insulating layer ILD may be formed in a single-layered structure or a multi-layered structure including an inorganic insulating material such as silicon oxide SiO_{X}, silicon nitride SiN_{X}, aluminum oxide Al₂O₃, and the like.

The power line contact portion SBC1 may be provided on the interlayer insulating layer ILD and may be electrically connected to the at least one power shorting bar SB1. For example, the power line contact portion SBC1 may be formed of the same material as source/drain electrodes of the thin film transistor on the same layer. The buffer layer BF and the interlayer insulating layer ILD may be disposed between the power line contact portion SBC1 and the at least one power shorting bar SB1. The at least one power shorting bar SB1 and the power line contact portion SB1 may be electrically connected to each other through a contact hole penetrating the buffer layer BF and the interlayer insulating layer ILD. For example, the power line contact portion SBC1 may electrically connect the at least one power shorting bar SB1 spaced apart from each other in some sections. In addition, the power line contact portion SBC1 may be electrically connected to the pixel power line VDDL extending in the first direction (or Y-axis direction) in the display area DA.

A first passivation layer PAS1 may be disposed on the interlayer insulating layer ILD on which the power line contact portion SBC1 is disposed. A second passivation layer PAS2 may be disposed on the first passivation layer PAS1. The first passivation layer PAS1 and the second passivation layer PAS2 may be formed in a single-layered structure or a multi-layered structure including an inorganic insulating material such as silicon oxide SiO_{X}, silicon nitride SiN_{X}, aluminum oxide Al₂O₃, and the like.

A block pattern BP may be disposed on the first passivation layer PAS1. For example, the block pattern BP may be disposed at a portion where the at least one power shorting bar SB1 and the undercut line UCL intersect. For example, the block pattern BP may be disposed between the at least one undercut line UCL and the at least one power shorting bar SB1. Also, the block pattern BP may be disposed between the at least one undercut line UCL and the power line contact portion SBC1. The block pattern BP prevents the power line contact portion SBC1 and the at least one power shorting bar SB1 from being damaged by an etchant used when the undercut line UCL is formed. For example, the block pattern BP may be formed of the same material as another signal line provided on the first passivation layer PAS1.

A planarization layer PLN for planarizing a step difference by the thin film transistor and the plurality of signal lines may be disposed on the second passivation layer PAS2. The planarization layer PLN may be formed of an organic material such as acryl resin, epoxy resin, phenolic resin, polyamide resin, polyimide resin, or the like. A first electrode, an organic light emitting layer and second electrodes of the light emitting element and a bank layer BA may be disposed on the planarization layer PLN. For example, the bank layer BA may be formed of an organic film such as acryl resin, epoxy resin, phenolic resin, polyamide resin, and polyimide resin.

At least one undercut line UCL in the pad area PA of the non-display area NDA on the substrate 111 may be configured by using the planarization layer PLN and the second passivation layer PAS2. For example, the at least one undercut line UCL may be configured by removing at least a portion of the planarization layer PLN and the second passivation layer PAS2. The at least one undercut line UCL may include a first pattern line UCL_P1 formed of the same material as the planarization layer PLN and a second pattern line UCL_P2 configured to support the first pattern line UCL_P1 and formed by removing at least a portion of the second passivation layer PAS2 to have an undercut area UCA under the first pattern line UCL_P1.

According to another embodiment of the present disclosure, the transparent display panel 110 may further include an organic pattern OP disposed in the periphery of the at least one undercut line UCL overlapping the at least one power shorting bar SB1 in the pad area PA of the non-display area NDA on the substrate 111. For example, the organic pattern OP may be disposed at one side or the other side of the at least one undercut line UCL. Alternatively, the organic pattern OP may be disposed between the plurality of adjacent undercut lines UCL, but embodiments of the present disclosure are not limited thereto.

The organic pattern OP may reduce the change in voltage or current supplied through the at least one power shorting bar SB1 disposed in the pad area PA of the non-display area NDA. For example, the organic pattern OP may include a first organic pattern OP_P1 formed of the same material as the planarization layer PLN and a second organic pattern OP_P2 formed of the same material as the bank layer BA. The organic pattern OP covers an upper portion of the at least one shorting bar SB1 with a predetermined thickness, thereby preventing noise caused by the voltage or current supplied through the at least one shorting bar SB1 from being propagated to another signal line.

Referring to FIG. 11, at least one power shorting bar SB2 may be disposed in the non-pad area NPA of the non-display area NDA on the substrate 111. The at least one power shorting bar SB2 may extend in the second direction (or X-axis direction) in the non-pad area NPA. The at least one power shorting bar SB2 may be disposed to intersect and overlap with at the least one undercut line UCL in the non-pad area NPA.

The at least one power shorting bar SB2 may be disposed in the non-pad area NPA on the substrate 111. For example, the at least one power shorting bar SB2 may be a pixel power shorting bar SB2 connected to the pixel power line VDDL (or first power line) extending in the first direction (or Y-axis direction) in the display area DA and configured to supply a first power. The at least one power shorting bar SB2 disposed in the non-pad area NPA may be formed of the same material as the gate electrode of the thin film transistor on the same layer, but embodiments of the present disclosure are not limited thereto. A gate insulating layer GI may be disposed between the at least one power shorting bar SB2 and the buffer layer BF.

The at least one power shorting bar SB2 in the non-pad area NPA on the substrate 111 may be partially spaced apart for the connection with other configurations in some sections. The at least one power shorting bar SB2 may include a contact portion to be electrically connected to the pixel power line VDDL extending in the first direction (or Y-axis direction) in the display area DA.

An interlayer insulating layer ILD may be disposed on the buffer layer BF on which the at least one power shorting bar SB2 and the gate electrode of the thin film transistor are disposed. The interlayer insulating layer ILD may be formed in a single-layered structure or a multi-layered structure including an inorganic insulating material such as silicon oxide SiO_{X}, silicon nitride SiN_{X}, aluminum oxide Al₂O₃, and the like.

The interlayer insulating layer ILD may include a power line contact portion SBC2 electrically connected to the at least one power shorting bar SB2.

For example, the power line contact portion SBC2 may be formed of the same material as source/drain electrodes of the thin film transistor on the same layer. The interlayer insulating layer ILD may be disposed between the power line contact portion SBC2 and the at least one power shorting bar SB2. The power line contact portion SBC2 and the at least one power shorting bar SB2 may be electrically connected to each other through a contact hole passing through the interlayer insulating layer ILD. For example, the power line contact portion SBC2 may electrically connect the power shorting bars SB2 spaced apart from each other in some sections. Also, the power line contact portion SBC2 may be electrically connected to the pixel power line VDDL extending in the first direction (or Y-axis direction) in the display area DA.

A first passivation layer PAS1 may be disposed on the interlayer insulating layer ILD on which the power line contact portion SBC2 is disposed. A second passivation layer PAS2 may be disposed on the first passivation layer PAS1. The first passivation layer PAS1 and the second passivation layer PAS2 may be formed in a single-layered structure or a multi-layered structure including an inorganic insulating material such as silicon oxide SiO_{X}, silicon nitride SiN_{X}, aluminum oxide Al₂O₃, and the like.

A block pattern BP may be disposed on the first passivation layer PAS1. For example, the block pattern BP may be disposed at a portion where the at least one power shorting bar SB2 and the undercut line UCL intersect. For example, the block pattern BP may be disposed between the at least one undercut line UCL and the at least one power shorting bar SB2. Also, the block pattern BP may be disposed between the at least one undercut line UCL and the power line contact portion SBC2. The block pattern BP may prevent the at least one power shorting bar SB2 and the power line contact portion SBC2 from being damaged by an etchant used when the undercut line UCL is formed. For example, the block pattern BP may be formed of the same material as another signal line formed on the first passivation layer PAS1.

A planarization layer PLN for planarizing a step difference by the thin film transistor and the plurality of signal lines may be disposed on the second passivation layer PAS2. The planarization layer PLN may be formed of n organic material such as acryl resin, epoxy resin, phenolic resin, polyamide resin, polyimide resin, or the like. A first electrode, an organic light emitting layer, and second electrodes of the light emitting element and a bank layer BA may be disposed on the planarization layer PLN. For example, the bank layer BA may be formed of an organic film such as acryl resin, epoxy resin, phenolic resin, polyamide resin, and polyimide resin.

At least one undercut line UCL in the non-pad area NPA of the non-display area NDA on the substrate 111 may be configured by using the planarization layer PLN and the second passivation layer PAS2. For example, the at least one undercut line UCL may be configured by removing at least a portion of the planarization layer PLN and the second passivation layer PAS2. The at least one undercut line UCL may include a first pattern line UCL_P1 formed of the same material as the planarization layer PLN and a second pattern line UCL_P2 configured to support the first pattern line UCL_P1 and formed by removing at least a portion of the second passivation layer PAS2 to have an undercut area UCA under the first pattern line UCL_P1.

According to another embodiment of the present disclosure, the transparent display panel 110 may further include an organic pattern OP disposed in the periphery of the at least one undercut line UCL overlapping at least one power shorting bar SB2 in the non-pad area NPA of the non-display area NDA on the substrate 111. For example, the organic pattern OP may be disposed at one side or the other side of the at least one undercut line UCL. Alternatively, the organic pattern OP may be disposed between the plurality of adjacent undercut lines UCL, but embodiments of the present disclosure are not limited thereto.

The organic pattern OP may reduce the change in voltage or current supplied through at least one power shorting bar SB2 disposed in the non-pad area NPA of the non-display area NDA. For example, the organic pattern OP may include a first organic pattern OP_P1 formed of the same material as the planarization layer PLN and a second organic pattern OP_P2 formed of the same material as the bank layer BA. The organic pattern OP covers an upper portion of the at least one shorting bar SB2 with a predetermined thickness, thereby preventing noise caused by the voltage or current supplied through at least one shorting bar SB2 from being propagated to another signal line.

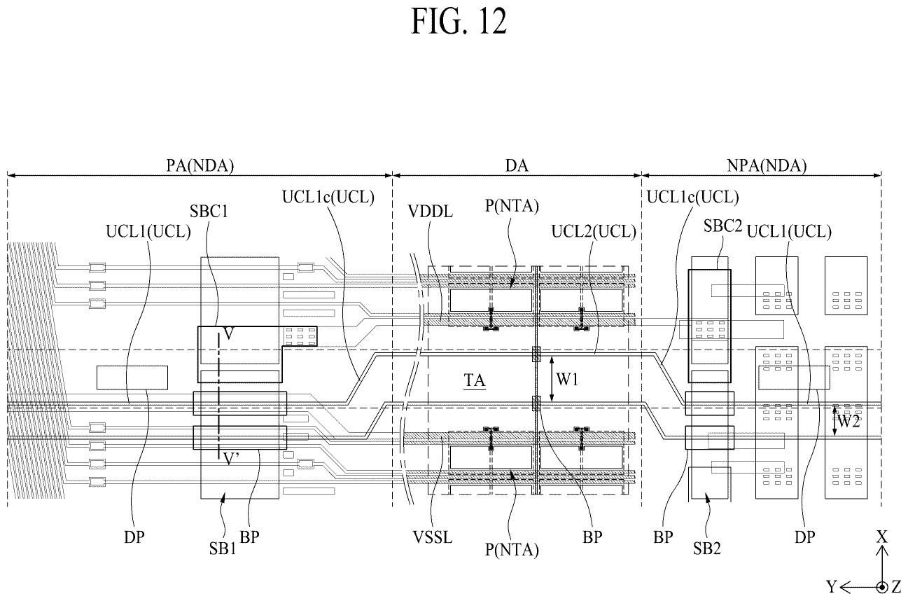

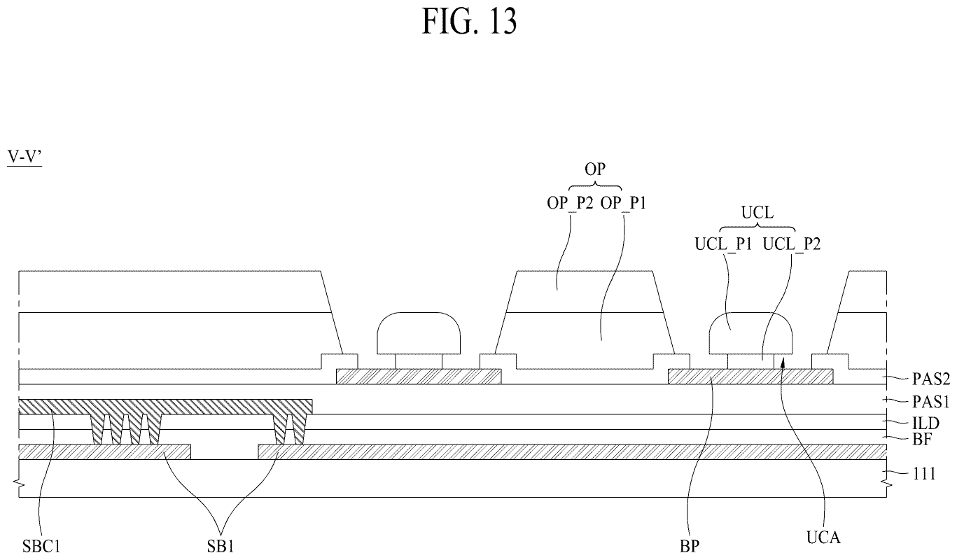

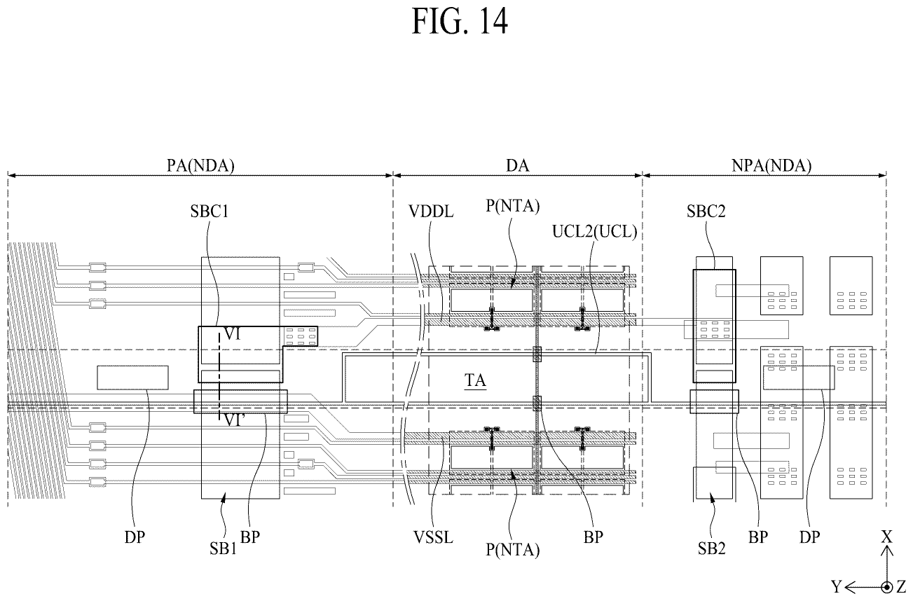

FIG. 12 illustrates a region C shown in FIG. 7 according to another embodiment of the present disclosure. FIG. 13 is a cross-sectional view along V-V′ of FIG. 12 according to another embodiment of the present disclosure.

FIGS. 12 and 13 may be configured by changing a configuration of at least one undercut line in the transparent display panel 110 described with reference to FIGS. 1 to 11. Accordingly, in the following description, the same reference numerals are assigned to the same elements except for the changed configuration, and a redundant description thereof will be omitted or briefly described.

Referring to FIGS. 12 and 13, in a transparent display panel 110 according to another embodiment of the present disclosure, at least one undercut line UCL may be disposed in a non-display area NDA and a display area DA. The at least one undercut line UCL may include at least one first undercut line UCL1 disposed in the non-display area NDA and at least one second undercut line UCL2 disposed in the display area DA. The at least one first undercut line UCL1 may be disposed in parallel with the at least one second undercut line UCL2 in a first direction (or Y-axis direction) to be extended to another line. The at least one second undercut line UCL2 may be disposed to extend in the first direction (or Y-axis direction) in a transmission area TA of respective pixels P disposed in the display area DA. The at least one second undercut line UCL2 may be disposed on one side and the other side in a second direction (or X-axis direction) in the transmission area TA.

The at least one first undercut line UCL1 is disposed in the non-display area NDA, the at least one second undercut line UCL2 is disposed in the display area DA, and the at least one first undercut line UCL1 and the at least one second undercut line UCL2 may be disposed in different lines parallel to the first direction (or Y-axis direction). The at least one first undercut line UCL1 may be bent at least twice in the non-display area NDA and may be connected to the at least one second undercut line UCL2. For example, the at least one first undercut line UCL1 extends in the first direction (or Y-axis direction) in the non-display area NDA and then extends in a third direction (or diagonal direction) between the first direction (or Y-axis direction) and second direction (or X-axis direction), and then is bent in the first direction (or Y-axis direction) around the display area DA, whereby the at least one first undercut line UCL1 may be disposed to extend in the same line as the at least one second undercut line UCL2. For example, the at least one first undercut line UCL1 may be disposed at predetermined intervals while being not overlapped with power line contact portions SBC1 and SBC2 in the non-display area NDA and may be configured to be extended in the same line as the at least one second undercut line UCL2 disposed in the display area DA after bypassing the power line contact portions SBC1 and SBC2. For example, the at least one first undercut line UCL1 may include an undercut connection pattern UCL1c extending in the third direction (or diagonal direction) in a portion adjacent to the at least one second undercut line UCL2. For example, the undercut connection pattern UCL1c may be disposed between the first undercut line UCL1 and the second undercut line UCL2.

The at least one first undercut line UCL1 may be disposed to be symmetrical to each other in the pad area PA of the non-display area NDA and the non-pad area NPA of the non-display area NDA. For example, a portion of the at least one first undercut line UCL1 disposed in the pad area PA and a portion of the at least one first undercut line UCL1 disposed in the non-pad area NPA may be disposed in the same line with the display area DA interposed therebetween, but embodiments of the present disclosure are not limited thereto.

The at least one second undercut line UCL2 may include a plurality of second undercut lines UCL2 spaced apart from each other in the second direction (or X-axis direction) in the transmission area TA of the display area DA. For example, the plurality of second undercut lines UCL2 may be spaced apart from each other to have a first width W1 in the second direction (or X-axis direction).

The at least one first undercut line UCL1 may include the plurality of first undercut lines UCL1 spaced apart from each other in the second direction (or X-axis direction) in the non-display area NPA. For example, the plurality of first undercut lines UCL1 may be spaced apart from each other to have a second width W2 in the second direction (or X-axis direction). The second width W2 of the plurality of first undercut lines UCL1 may be equal to or less than the first width W1 of the plurality of second undercut lines UCL2. For example, the first width W1 of the plurality of second undercut lines UCL2 may be smaller than the width in the second direction (or X-axis direction) of the transmission area TA of the display area DA, and the second width W2 of the plurality of first undercut lines UCL1 may be smaller than the first width W1 of the plurality of second undercut lines UCL2, but embodiments of the present disclosure are not limited thereto.

Referring to FIG. 13, in the pad area PA on the substrate 111, the at least one first undercut line UCL1 may be disposed to overlap the at least one power shorting bar SB1 and may be disposed not to overlap the power line contact portion SB1 connected to the at least one power shorting bar SB1.

The at least one first undercut line UCL1 is disposed not to overlap the power line contact portion SBC1 with the first passivation layer PAS1 interposed therebetween, thereby preventing the power line contact portion SBC1 from being damaged in a process of forming the at least one first undercut line UCL1. Accordingly, the transparent display panel 110 according to another embodiment of the present disclosure prevent the deterioration of process reliability due to the formation of at least one undercut line UCL1.

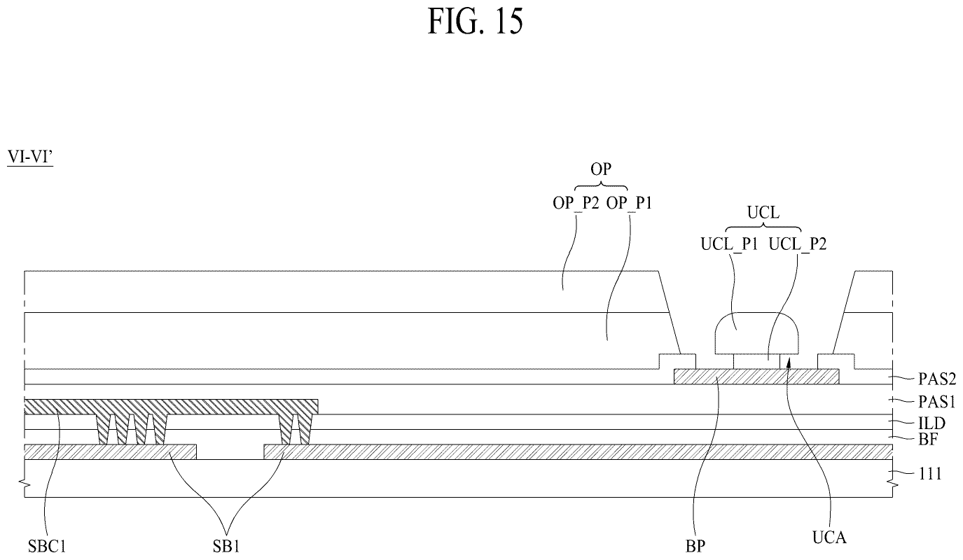

FIG. 14 illustrates a region C shown in FIG. 7 according to another embodiment of the present disclosure. FIG. 15 is a cross-sectional view along VI-VI′ of FIG. 14 according to another embodiment of the present disclosure. FIGS. 14 and 15 may be configured by changing a configuration of at least one undercut line in the transparent display panel 110 described with reference to FIGS. 1 to 13. Accordingly, in the following description, the same reference numerals are assigned to the same elements except for the changed configuration, and a redundant description thereof will be omitted or briefly described.

Referring to FIGS. 14 and 15, a transparent display panel 110 according to another embodiment of the present disclosure may be disposed in a non-display area NDA and a display area DA. At least one undercut line UCL may include at least one first undercut line UCL1 disposed in the non-display area NDA and at least one second undercut line UCL2 disposed in the display area DA. The at least one second undercut line UCL2 may be disposed to extend in the first direction (or Y-axis direction) in the transmission area TA of each of pixels P disposed in the display area DA. The at least one second undercut line UCL2 may be disposed on one side and the other side in the second direction (or X-axis direction) in the transmission area TA. The at least one second undercut line UCL2 may include a plurality of second undercut lines UCL2 spaced apart from each other in the second direction (or X-axis direction) in the transmission area TA.

The at least one first undercut line UCL1 may be disposed in the non-display area NDA and may be configured in the same or less number as the plurality of second undercut lines UCL2. For example, the at least one first undercut line UCL1 may be configured to be a smaller number than the plurality of second undercut lines UCL2. The at least one first undercut line UCL1 may be disposed in the same line along the first direction (or Y-axis direction) with any one of the plurality of second undercut lines UCL2. For example, the at least one first undercut line UCL1 may extend in the first direction (or Y-axis direction) in the non-display area NDA and may be connected to one of the plurality of second undercut lines UCL2 disposed in the display area DA. For example, the at least one first undercut line UCL1 may be configured to bypass the power line contact portions SBC1 and SBC2 of at least one power shorting bar SB1 and SB2 in the non-display area NDA. For example, the at least one first undercut line UCL1 may extend in the line which does not overlap the power line contact portion SBC1 and SBC2 in the non-display area NDA, and may be configured to be connected to the undercut line UCL2 disposed on the line which does not overlap the power line contact portion SBC1 and SBC2 among the plurality of second undercut lines UCL2.

For example, the at least one first undercut line UCL1 may include an undercut connection pattern UCL1c protruding to be connected to the undercut line UCL2 disposed on the other line of the plurality of second undercut lines UCL2 in a portion adjacent to the plurality of second undercut lines UCL2. For example, the undercut connection pattern UCL1c may protrude in the second direction (or X-axis direction) from the at least one first undercut line UCL1. The undercut connection pattern UCL1c may be disposed between the first undercut line UCL1 and the second undercut line UCL2 disposed on the other line of the plurality of second undercut lines UCL2.

The at least one first undercut line UCL1 may be disposed to extend in the same line on the pad area PA of the non-display area NDA and the non-pad area NPA of the non-display area NDA. For example, a portion of the at least one first undercut line UCL1 disposed in the pad area PA and a portion of the at least one first undercut line UCL1 disposed in the non-pad area NPA may be disposed to extend in the same line with the display area DA interposed therebetween, but embodiments of the present disclosure are not limited thereto.

Referring to FIG. 15, in the pad area PA on the substrate 111, the at least one first undercut line UCL1 may be disposed to overlap the at least one power shorting bar SB1 and may be disposed not to overlap the power line contact portion SB1 connected to the at least one power shorting bar SB1.

The at least one first undercut line UCL1 is disposed not to overlap the power line contact portion SBC1 disposed with the first passivation layer PAS1 interposed therebetween, thereby preventing the power line contact portion SBC1 from being damaged in a process of forming the at least one first undercut line UCL1. Accordingly, the transparent display panel 110 according to another embodiment of the present disclosure prevents the deterioration of process reliability by the formation of at least one undercut line UCL1.

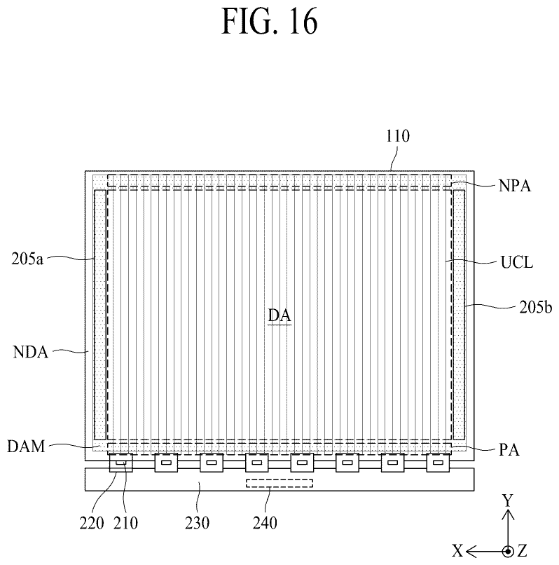

FIG. 16 illustrates a transparent display apparatus according to another embodiment of the present disclosure.

Referring to FIG. 16, a transparent display panel 110 according to another embodiment of the present disclosure may include a display area DA in which pixels are configured to display an image and a non-display area NDA that does not display an image. For example, the non-display area NDA may be disposed in the periphery of the display area DA.

The transparent display panel 110 according to another embodiment of the present disclosure may include at least one undercut line extending to the non-display area NDA and the display area DA. For example, the at least one undercut line UCL may be arranged to extend in a first direction (or Y-axis direction) in the non-display area NDA and the display area DA. For example, the at least one undercut line UCL may extend from the non-display area NDA to the display area DA. In at least a portion of the non-display area NDA, an organic light emitting layer constituting a light emitting element may extend from the display area DA, and the at least one undercut line UCL may extend from the portion in which the organic light emitting layer is disposed in the non-display area NDA to the display area DA. For example, the at least one undercut line UCL may extend from a pad area PA of the non-display area NDA to cross the display area DA and may extend to a non-pad area NPA of the non-display area NDA.

The transparent display panel 110 may include a dam pattern DAM surrounding the display area DA when seen from a plan view. The dam pattern DAM may be configured in the form of closed loop shape surrounding the non-display area NDA in the periphery of the display area DA from a plan view. For example, the closed loop shape of the dam pattern DAM may be configured in a rectangular shape.

The transparent display panel 110 may include a plurality of gate drivers 205a and 205b. The transparent display panel 110 may include a source drive integrated circuit IC 210, a flexible film 220, a circuit board 230, and a timing controller 240.

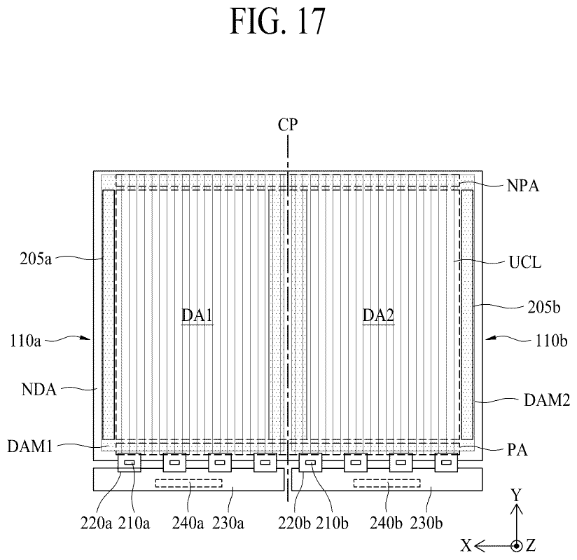

FIG. 17 illustrates a transparent display apparatus according to another embodiment of the present disclosure.

Referring to FIG. 17, a transparent display panel 110 according to another embodiment of the present disclosure may include a dam pattern DAM1 and DAM2 for dividing a display area DA into at least two or more areas. The dam pattern DAM1 and DAM2 may be configured in the form of closed loop that surrounds at least a portion of non-display area NDA and display area DA so that the display area DA may be divided into two or more areas DA. For example, the dam pattern DAM1 and DAM2 may include the first dam pattern DAM1 and the second dam pattern DAM2.

The first dam pattern DAM1 may be configured to surround the display area DA located on the left in a second direction (or X-axis direction). The second dam pattern DAM2 may be configured to surround the display area DA located on the right in the second direction (or X-axis direction).

The first dam pattern DAM1 and the second dam pattern DAM2 may be spaced apart from each other in the second direction (or X-axis direction). Alternatively, at least a portion of adjacent parts of the first dam pattern DAM1 and the second dam pattern DAM2 may overlap each other.

The transparent display panel 110 may include a plurality of gate drivers 205a and 205b. For example, the plurality of gate drivers 205a and 205b may include the first gate driver 205a and the second gate driver 205b. The first gate driver 205a is arranged in the non-display area NDA located on the left in the second direction (or X-axis direction), and the second gate driver 205b is arranged in the non-display area NDA located on the right in the second direction (or X-axis direction). For example, the first dam pattern DAM1 may be disposed to surround a portion of the left side of the display area DA and the first gate driver 205a, and the second dam pattern DAM2 may be disposed to surround a portion of the right side of the display area DA and the second gate driver 205b.

The transparent display panel 110 may include first and second source drive integrated circuits ICs 210a and 210b, first and second flexible films 220a and 220b, first and second circuit boards 230a and 230b, and first and second timing controllers 240a and 240b.

The first source drive IC 210a, the first flexible film 220a, the first circuit board 230a, and the first timing controller 240a may be connected to the left-sided display area DA defined by the first dam pattern DAM1, and the second source drive IC 210b, the second flexible film 220b, the second circuit board 230b, and the second timing controller 240b may be connected to the left-sided display area DA defined by the second dam pattern DAM2.

At least a portion of the first dam pattern DAM1 and the second dam pattern DAM2 may be disposed in parallel with at least one undercut line UCL disposed in the non-display area NDA and the display area DA. For example, the at least one undercut line UCL may be disposed to overlap the first dam pattern DAM1 and the second dam pattern DAM2.

A cutting portion CP may be provided between the first dam pattern DAM1 and the second dam pattern DAM2. The cutting portion CP may be the portion in which the transparent display panel 110 may be separated or cut through a cutting device such as laser or wheel. The transparent display panel 110 may secure moisture permeation reliability by the at least one undercut line UCL disposed in parallel with the first and second dam patterns DAM1 and DAM2 even when the cutting portion CP is cut. Each of the first and second display areas DA1 and DA2 surrounded by the first and second dam patterns DAM1 and DAM2 may be provided with a moisture permeation preventing structure by the at least one undercut line UCL, and the respective first and second display areas DA1 and DA2 may be the first transparent display panel 110a and the second transparent display panel 110b which are independently provided by the separation or cutting of the cutting portion CP.

The first and second dam patterns DAM1 and DAM2 may be non-display areas NDA (or bezel areas) of the respective first and second transparent display panels 110a and 110b separated from each other. For example, a central portion of the display area DA in which the first and second dam patterns DAM1 and DAM2 cross in the first direction (or Y-axis direction) may be the display area DA before the cutting process, however, it may be the non-display area NDA (or bezel area) after the cutting process.

A transparent display apparatus according to one or more embodiments of the present disclosure will be described below.

A transparent display apparatus according to one or more embodiments of the present disclosure may include a substrate including a display area and a non-display area, the display area being provided with a transmission area and a non-transmission area including an emission area in which a light emitting element is disposed, and the non-display area being provided in a periphery of the display area, at least one power line disposed in the non-transmission area of the display area on the substrate and configured to extend in a first direction, a power shorting bar disposed in the non-display area on the substrate, electrically connected to the at least one power line, and extending in a second direction transverse to the first direction, and at least one undercut line disposed in the display area and the non-display area on the substrate and extending in the first direction.

According to one or more embodiments of the present disclosure, the display apparatus may further comprise a passivation layer disposed over the substrate; and a planarization layer disposed on the passivation layer, wherein the at least one undercut line includes a first pattern line and a second pattern line, the first pattern line being formed by patterning the planarization layer, and the second pattern line being formed by removing at least a portion of the passivation layer to have an undercut area under the first pattern line.

According to one or more embodiments of the present disclosure, the power shorting bar may include a plurality of slit structures.

According to one or more embodiments of the present disclosure, the power shorting bar may be configured to have the plurality of slit structures in a portion overlapping the at least one power line.

According to one or more embodiments of the present disclosure, the display apparatus may further comprise a block pattern disposed at a portion where the at least one undercut line and the at least one power line overlap each other.

According to one or more embodiments of the present disclosure, the display apparatus may further comprise an organic pattern covering an upper portion of the power shorting bar.

According to one or more embodiments of the present disclosure, the display apparatus may further comprise a planarization layer disposed over the substrate; and a bank layer disposed on the planarization layer, wherein the organic pattern includes a first organic pattern formed of a same material as the planarization layer and a second organic pattern formed of a same material as the bank layer.

According to one or more embodiments of the present disclosure, the at least one undercut line may extend from the non-display area to the display area.

According to one or more embodiments of the present disclosure, the at least one undercut line may be disposed in the transmission area in the display area.

According to one or more embodiments of the present disclosure, the light emitting element may include an organic light emitting layer, the light emitting element being disposed to extend from the display area to at least a portion of the non-display area, and the at least one undercut line may extend from the non-display area in which the organic light emitting layer is disposed to the display area.

According to one or more embodiments of the present disclosure, at least a portion of the at least one undercut line may overlap the power shorting bar in the non-display area.

According to one or more embodiments of the present disclosure, the at least one undercut line may include at least one first undercut line disposed in the non-display area, and at least one second undercut line disposed in the transmission area of the display area.

According to one or more embodiments of the present disclosure, the at least one first undercut line may be arranged in a same line as the at least one second undercut line in the first direction.

According to one or more embodiments of the present disclosure, the at least one first undercut line may be disposed on another line in parallel with the at least one second undercut line in the first direction.

According to one or more embodiments of the present disclosure, the at least one first undercut line may be bent at least twice in the non-display area and may be connected to the at least one second undercut line.

According to one or more embodiments of the present disclosure, the at least one first undercut line may be configured to bypass a contact portion of the power shorting bar and the at least one power line in the non-display area.

According to one or more embodiments of the present disclosure, the at least one first undercut line may do not overlap a contact portion of the at least one power line and the power shorting bar in the non-display area and may be disposed adjacent to the at least one power line.

According to one or more embodiments of the present disclosure, the at least one second undercut line may be arranged on one side in the second direction in the transmission area or may be arranged on the other side in the second direction.

According to one or more embodiments of the present disclosure, the at least one second undercut line may include a plurality of second undercut lines spaced apart from each other in the second direction in the transmission area, and the plurality of second undercut lines may be respectively disposed on one side and the other side in the second direction.

According to one or more embodiments of the present disclosure, a number of the at least one first undercut line may be equal to or less than a number of the plurality of second undercut lines.

According to one or more embodiments of the present disclosure, the at least one first undercut line may be disposed in a same line along the first direction as any one of the plurality of second undercut lines.

According to one or more embodiments of the present disclosure, the at least one first undercut line may include a connection pattern protruding in the second direction, and the connection pattern may be connected to the other one of the at least one first undercut line and the plurality of second undercut lines.

According to one or more embodiments of the present disclosure, the at least one first undercut line may be disposed to bypass a contact portion of the power shorting bar and the at least one power line in the non-display area.

According to one or more embodiments of the present disclosure, may further include at least one organic insulating layer on the substrate, and at least one inorganic insulating layer between the substrate and the at least one organic insulating layer, the at least one undercut line may be formed by removing at least a portion of the at least one organic insulating layer and the at least one inorganic insulating layer.

According to one or more embodiments of the present disclosure, the at least one undercut line may separate or disconnect an organic light emitting layer constituting the light emitting element.

According to one or more embodiments of the present disclosure, may further include a block pattern disposed at a portion where the at least one undercut line and the power shorting bar overlap each other.

According to one or more embodiments of the present disclosure, the block pattern may be disposed on the at least one inorganic insulating layer between the at least one undercut line and the power shorting bar.

According to one or more embodiments of the present disclosure, may further include an organic pattern disposed in a periphery of the at least one undercut line overlapped with the power shorting bar.

According to one or more embodiments of the present disclosure, the organic pattern may include at least a portion of the at least one organic insulating layer.

According to one or more embodiments of the present disclosure, may further include a dummy electrode pattern disposed in a periphery of the at least one undercut line disposed in the non-display area.

According to one or more embodiments of the present disclosure, the dummy electrode pattern may include a same material as a first electrode constituting the light emitting element.

According to one or more embodiments of the present disclosure, may further include a dam pattern disposed in the non-display area on the substrate.

According to one or more embodiments of the present disclosure, the dam pattern on the substrate may include a closed loop shape surrounding the non-display area from a plan view.

According to one or more embodiments of the present disclosure, at least a portion of the dam pattern may be disposed in parallel with the at least one undercut line.

According to one or more embodiments of the present disclosure, the at least one undercut line may overlap the dam pattern.

It will be apparent to those skilled in the art that various modifications and variations may be made in the apparatus of the present disclosure without departing from the scope of the disclosure. Thus, it is intended that the present disclosure cover the modifications and variations of this disclosure provided that within the scope of the claims and their equivalents.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A transparent display apparatus comprising:
a substrate including a display area and a non-display area, wherein the display area is provided with a transmission area and a non-transmission area including an emission area in which a light emitting element is disposed, and the non-display area is provided in a periphery of the display area;
at least one power line disposed in the non-transmission area of the display area on the substrate, the at least one power line configured to extend in a first direction;
a power shorting bar disposed in the non-display area on the substrate, the power shorting bar electrically connected to the at least one power line, the power shorting bar extending in a second direction transverse to the first direction; and
at least one undercut line disposed in the display area and the non-display area on the substrate, the at least one undercut line extending in the first direction.

2. The transparent display apparatus according to claim 1, further comprising;
a passivation layer disposed over the substrate; and
a planarization layer disposed on the passivation layer,
wherein the at least one undercut line includes a first pattern line and a second pattern line, the first pattern line being formed by patterning the planarization layer, and the second pattern line being formed by removing at least a portion of the passivation layer to have an undercut area under the first pattern line.

3. The transparent display apparatus according to claim 1, wherein the power shorting bar includes a plurality of slit structures.

4. The transparent display apparatus according to claim 3, wherein the power shorting bar is configured to have the plurality of slit structures in a portion overlapping the at least one power line.

5. The transparent display apparatus according to claim 1, further comprising a block pattern disposed at a portion where the at least one undercut line and the at least one power line overlap each other.

6. The transparent display apparatus according to claim 1, further comprising an organic pattern covering an upper portion of the power shorting bar.

7. The transparent display apparatus according to claim 6, further comprising:
a planarization layer disposed over the substrate; and
a bank layer disposed on the planarization layer,
wherein the organic pattern includes a first organic pattern formed of a same material as the planarization layer and a second organic pattern formed of a same material as the bank layer.

8. The transparent display apparatus according to claim 1, wherein the at least one undercut line extends from the non-display area to the display area.

9. The transparent display apparatus according to claim 1, wherein the at least one undercut line is disposed in the transmission area in the display area.

10. The transparent display apparatus according to claim 1,
wherein the light emitting element includes an organic light emitting layer, the organic light emitting layer being disposed to extend from the display area to at least a portion of the non-display area, and
wherein an the at least one undercut line extends from the non-display area in which the organic light emitting layer is disposed to the display area.

11. The transparent display apparatus according to claim 1, wherein at least a portion of the at least one undercut line overlaps the power shorting bar in the non-display area.

12. The transparent display apparatus according to claim 1,
wherein the at least one undercut line includes:
at least one first undercut line disposed in the non-display area; and
at least one second undercut line disposed in the transmission area of the display area.

13. The transparent display apparatus according to claim 12, wherein the at least one first undercut line is arranged in a same line as the at least one second undercut line in the first direction.

14. The transparent display apparatus according to claim 12, wherein the at least one first undercut line is disposed on another line in parallel with the at least one second undercut line in the first direction.

15. The transparent display apparatus according to claim 14, wherein the at least one first undercut line is bent at least twice in the non-display area and is connected to the at least one second undercut line.

16. The transparent display apparatus according to claim 15,
wherein the at least one first undercut line is configured to bypass a contact portion of the power shorting bar and the at least one power line in the non-display area.

17. The transparent display apparatus according to claim 12, wherein the at least one first undercut line does not overlap a contact portion of the at least one power line and the power shorting bar in the non-display area and is disposed adjacent to the at least one power line.

18. The transparent display apparatus according to claim 12, wherein the at least one second undercut line is arranged on one side in the second direction in the transmission area or is arranged on the other side in the second direction.

19. The transparent display apparatus according to claim 12, wherein the at least one second undercut line includes a plurality of second undercut lines spaced apart from each other in the second direction in the transmission area, and the plurality of second undercut lines are respectively disposed on one side and the other side in the second direction.

20. The transparent display apparatus according to claim 19, wherein a number of the at least one first undercut line is equal to or less than a number of the plurality of second undercut lines.

21. The transparent display apparatus according to claim 14, wherein the at least one first undercut line is disposed in a same line along the first direction as any one of the plurality of second undercut lines.

22. The transparent display apparatus according to claim 15,
wherein the at least one first undercut line includes a connection pattern protruding in the second direction, and
wherein the connection pattern is connected to the other one of the at least one first undercut line and the plurality of second undercut lines.

23. The transparent display apparatus according to claim 22, wherein the at least one first undercut line is disposed to bypass a contact portion of the power shorting bar and the at least one power line in the non-display area.

24. The transparent display apparatus according to claim 1, further comprising:
at least one organic insulating layer on the substrate; and
at least one inorganic insulating layer between the substrate and the at least one organic insulating layer,
wherein the at least one undercut line is formed by removing at least a portion of the at least one organic insulating layer and the at least one inorganic insulating layer.

25. The transparent display apparatus according to claim 24, wherein the at least one undercut line separates or disconnects an organic light emitting layer constituting the light emitting element.

26. The transparent display apparatus according to claim 24, further comprising a block pattern disposed at a portion where the at least one undercut line and the power shorting bar overlap each other.

27. The transparent display apparatus according to claim 26, wherein the block pattern is disposed on the at least one inorganic insulating layer between the at least one undercut line and the power shorting bar.

28. The transparent display apparatus according to claim 20, further comprising an organic pattern disposed in a periphery of the at least one undercut line overlapped with the power shorting bar.

29. The transparent display apparatus according to claim 28, wherein the organic pattern includes at least a portion of the at least one organic insulating layer.

30. The transparent display apparatus according to claim 1, further comprising a dummy electrode pattern disposed in a periphery of the at least one undercut line disposed in the non-display area.

31. The transparent display apparatus according to claim 24, wherein the dummy electrode pattern includes a same material as a first electrode constituting the light emitting element.

32. The transparent display apparatus according to claim 1, further comprising a dam pattern disposed in the non-display area on the substrate.

33. The transparent display apparatus according to claim 32, wherein the dam pattern on the substrate includes a closed loop shape surrounding the non-display area from a plan view.

34. The transparent display apparatus according to claim 33, wherein at least a portion of the dam pattern is disposed in parallel with the at least one undercut line.

35. The transparent display apparatus according to claim 34, wherein the at least one undercut line overlaps the dam pattern.
